(19) United States
(12) Patent Application Publication
(10) Pub. No.: US 2013/0208741 A1
(43) Pub. Date: Aug. 15, 2013

(54) Laser architectures

(71) Applicant: REALD INC., (US)

(72) Inventors: Robert Vanleeuwen, Ewing, NJ (US); Bing XU, Bayside, NY (US); Yihan Xiong, Lawrenceville, NJ (US); Jean-Francois Seurin, West Windsor,, NJ (US); Chuni Ghosh, West Windsor, NJ (US)

(73) Assignee: REALD INC., Beverly Hills, CA (US)

(21) Appl. No.: 13/764,770

(22) Filed: Feb. 11, 2013

Related U.S. Application Data
(60) Provisional application No. 61/598,175, filed on Feb. 13, 2012.

(51) Int. Cl. H01S 5/06

(52) U.S. Cl. CPC H01S 5/0605
USPC 372/22

(57) ABSTRACT

Disclosed herein are architectures for VCSEL systems. By using high power IR VCSEL element(s), a bulk doubling material can be used to double the IR light and generate visible light (red, green, blue, or UV light) in a cavity, in either continuous wave (CW) or pulsed mode. The reflectivity of the output distributed Bragg reflector (DBR) of these VCSELs can be designed to increase the power in the cavity, rather than the power in the VCSEL laser. By enabling the use of a bulk doubling material in the cavity and directly doubling the VCSEL the device can be inexpensive, simpler, high efficiency, better reliability, and vastly improved manufacturing and alignment tolerances. There are a number of cavity architectures that can be used to double the IR light from the VCSEL(s). The VCSEL(s) can be single elements, or arrays with high intensity elements.

### CROSS-REFERENCE TO RELATED APPLICATIONS

This application relates to and claims priority to U.S. Provisional Patent Application Ser. No. 61/598,175, filed Feb. 13, 2012 entitled “Laser architectures”, the entirety of which is herein incorporated by reference.

### TECHNICAL FIELD

The present disclosure generally relates to lasers, and more specifically, to high power infrared laser technologies and components including frequency doublers, solid state lasers, vertical cavity surface emitting lasers, and diodes used to make high power visible lasers.

### BACKGROUND

Generally, red, green, blue and ultraviolet (UV) lasers have many potential uses in illumination, medical, material processing, welding, and display. Cost, reliability, efficiency, size, and power are laser parameters that may be considered when selecting a laser for use in these various markets/technology fields. Display is an example of a market that has a number of different segments that value these parameters in slightly different ways. In the consumer display market, cost, efficiency, and size may be important parameters, while in the professional display market, reliability, high power, and cost may be key parameters. Cheap, reliable, highly efficient green, red, or blue source is important for all the above applications. Such a green laser source is particularly relevant since high power direct sources, such as Vertical Cavity Surface Emitting Lasers (VCSELs) or edge emitting diodes, do not yet exist at the appropriate wavelengths for professional display applications.

Generally, a full color display uses at least red, green, and blue light sources. When employed in movie theaters, these colors have to be in certain ranges to comply with the standards set by the movie industry, and more specifically, with the Digital Cinema Initiative. The approximate accepted color ranges for movies are given by red or 616-650 nm, green or 523-545 nm, and blue or 455-468 nm. However, consumer display markets do not have such a strict wavelength requirement. As red and blue diodes have become available, interest in lasers for backlighting and use in consumer projectors has increased. Direct laser sources are cost effective, reliable, and efficient sources of light. However, currently there is no high power green direct laser source having the wavelength needed for display. Thus, green is an important laser technology, and there is a need in the art for a high power, efficient green direct source of light. In addition, red lasers currently have very severe cooling requirements and their lifetimes are relatively limited.

### SUMMARY

Disclosed herein are novel architectures for VCSEL-based laser systems, as well as related methods of doubling the generated light from a VCSEL system to generate red, green, or blue light. In advantageous embodiments employing a high power IR VCSEL array of elements, a bulk (for example, crystal) doubling material may be used to double the infrared (IR) light and generate “visible” light (red, green, blue, or UV light) in an external cavity in either continuous wave (CW) or pulsed mode. By enabling the use of a bulk doubling material and directly doubling the frequency of the VCSEL, the device can be inexpensive, simpler, have high efficiency, better reliability, and vastly improved manufacturing and alignment tolerances. Moreover, if using PPLN (periodic poled Lithium Niobate) or other periodic poled materials as the frequency doubler, the use of high power array elements allows for the use of short materials (0.2 mm to 4 mm). This is critical because the longer the material, the more sensitive it is to alignment, temperature and wavelength. With the disclosed principles, there are a number of cavity architectures that can be used to double the IR light from VCSEL lasers, and the VCSEL(s) can be single elements, or arrays with high intensity elements.

In one embodiment, architecture for a vertical cavity surface emitting laser system may include at least one vertical cavity surface emitting laser (VCSEL) element. Such an exemplary architecture may further include a bulk crystal doubling material located in a cavity adjacent to the VCSEL element and configured to receive light emitted from the VCSEL element, and to substantially double the frequency of the received light. This embodiment of architecture may also include an output coupler configured to output the doubled light from the cavity and output said visible light for use in display illumination.

In another embodiment, an architecture for a vertical cavity surface emitting laser system may include at least one vertical cavity surface emitting laser (VCSEL) element configured to emit infrared light, and a cavity defined between the at least one VCSEL element and a mirror being highly reflective of infrared light. Such an exemplary architecture may further include a bulk crystal doubling material located in the cavity and configured to receive infrared light emitted from the VCSEL element, and to substantially double the frequency of the received infrared light to output visible light.

In yet another embodiment, an architecture for a vertical cavity surface emitting laser system may include at least one vertical cavity surface emitting laser (VCSEL) element configured to emit infrared light, and a bulk crystal doubling material located in a cavity adjacent to the VCSEL element and configured to receive infrared light emitted from the VCSEL element, and to substantially double the frequency of the received infrared light to output visible light. Such an exemplary architecture may further include a coating on an end of the doubling material opposite to the at least one VCSEL element, the coating being highly reflective of infrared light. In addition, such architecture may further include an etalon or dichroic mirror orientated near Brewster's angle and used as an output coupler configured to receive the doubled light from the doubling material and output said doubled light for use.

### BRIEF DESCRIPTION OF THE DRAWINGS

Embodiments are illustrated by way of example in the accompanying figures, in which like reference numbers indicate similar parts, and in which:

FIG. 1 is a schematic diagram illustrating one embodiment of a conventional VCSEL-based device;

FIG. 2 is a schematic diagram illustrating one embodiment of an architecture for a VCSEL array system, in accordance with the present disclosure;

FIG. 3 is a schematic diagram illustrating various VCSEL array layouts, in accordance with the present disclosure;

FIG. 4 is a schematic diagram illustrating one embodiment of the frequency doubling of a single VCSEL element, in accordance with the present disclosure;

FIG. 5 is a schematic diagram illustrating one embodiment of an architecture of a VCSEL-based light source in which power may be extracted from the cavity after passing through the doubling material twice (once in each direction), in accordance with the present disclosure;

FIG. 6 is a schematic diagram illustrating another embodiment of an architecture of a VCSEL-based light source which may include at least a micro-lens array, in accordance with the present disclosure;

FIG. 7 is a schematic diagram illustrating one embodiment of an architecture of a VCSEL-based light source that employs a 4F systems intra-cavity, in accordance with the present disclosure; and

FIG. 8 is a schematic diagram illustrating one embodiment of architecture of a VCSEL-based light source employing an output coupler to fold the 4F system, in accordance with the present disclosure.

### DETAILED DESCRIPTION

Generally, one embodiment of a VCSEL-based light source in accordance with the present disclosure may take the form of architecture for a VCSEL system that may use high power IR VCSEL element(s). A bulk crystal doubling material may be used to double the IR light and generate “visible” light (red, green, blue, or UV light) in an external cavity in either continuous wave or pulsed mode. The reflectivity of the output distributed Bragg reflector (DBR) of these VCSELs can be designed to increase the power in an external cavity rather than the power in the VCSEL laser. By enabling the use of shorter either bulk or periodically poled doubling material and directly doubling the power of the VCSEL, the device can be inexpensive, simpler, have higher efficiency, better reliability, and vastly improved manufacturing and alignment tolerances. There are a number of cavity architectures that can be used to double the IR light from the VCSEL(s) in accordance with the disclosed principles, and the VCSEL(s) can be single elements, or arrays with high intensity elements. Such arrays may be designed for high power per element, and designed and fabricated to increase power in the external cavity. In practice, arrays are needed to generate enough overall power out of the cavity to be commercially viable. Examples of required watts output range from 3 W to potentially hundreds of watts of visible power.

Generally, there are several approaches to green/blue/red lasers. For very low power applications in which the wavelength of the light is not as critical, direct diodes in the approximate range of 50-100 mW are available in the appropriate wavelength ranges. For example, these diodes are of interest in small, mobile, “pico” projectors for the consumer market. However, for high power applications these sources are not useful. For higher power applications, conventional approaches typically employ infrared wavelengths generated by a solid state laser and then doubled with a non-linear crystal. Typical examples may include the doubling of fiber lasers and solid state lasers using crystals and doped glasses, for example, the YAG laser, that are lamp or diode pumped. These lasers may generate high power, good quality IR light which can be doubled. High intensity and good quality are critical for efficient doubling of the IR light to make visible or UV light, for example, 1064 nm doubled to 532 nm (green light), while 1232 nm can be doubled to 616 nm (red light). While these current doubled solid state sources can generate a lot of power in the green wavelength, in the approximate range of a few Watts to thousands of Watts, solid state sources are expensive, complex, not very efficient, and are difficult to make reliable. For example, approximately 30,000 hours or more are commonly needed for professional display applications for which approximately 5 to 2000 Watts of visible light may be appropriate.

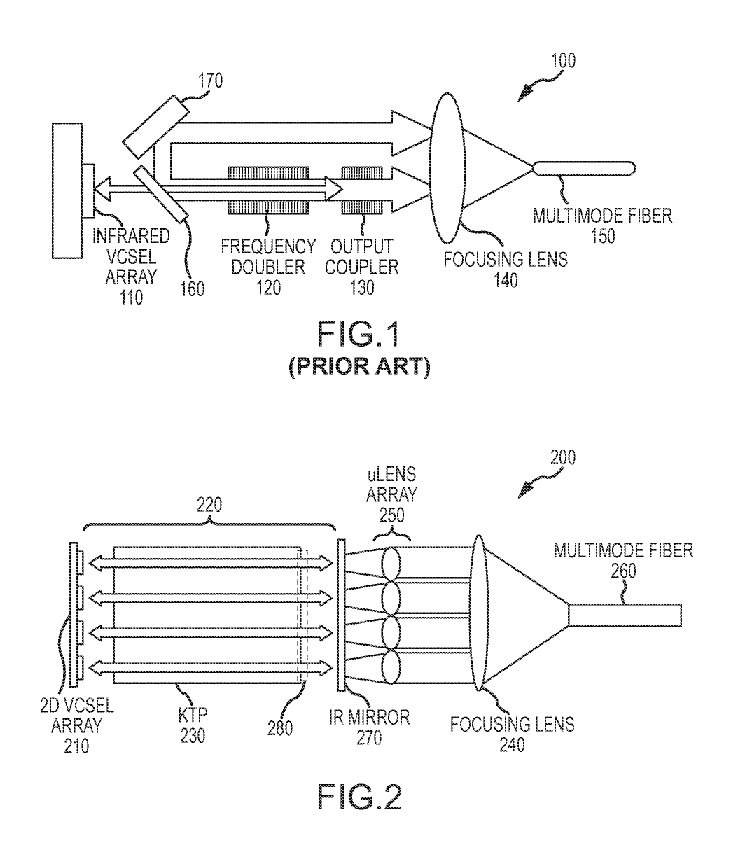

Another version of green or blue laser that has been produced uses a VCSEL array, such as the exemplary embodiment of a VCSEL array illustrated in FIG. 1. FIG. 1 is a schematic diagram illustrating one embodiment of a conventional VCSEL-based device 100. Unfortunately, VCSEL elements themselves do not typically output the appropriate power needed for preferred applications such as those identified above. For example, a VCSEL may output approximately 150 mW or less, and in the example of a VCSEL array have a spread of wavelengths, for example, greater than the approximate range of one to ten nanometers. Thus, a typical low power VCSEL element or VCSEL array may be difficult to efficiently frequency double with conventional architectures. The advantage of their use, however, is that VCSELs are extremely reliable and produce good quality IR light.

FIG. 1 illustrates a diagram of such a VCSEL-based device 100 from Necsel/Ushio that is commercially available. The VCSEL device 100 includes an infrared VCSEL array 110, a PPLN frequency doubler 120, a special output coupler (a volume Bragg grating (VBG) in this embodiment) 130, a focusing lens 140, and a multimode fiber 150 to carry the output light. Light illuminated from the VCSEL array 110 initially passes through a dichroic mirror 160. A first path passes through lens 160 to illuminate a frequency doubler 120 for doubling the frequency of the light. That light then passes to the volume Bragg grating (VBG) 130, which functions as an output coupler in this embodiment. This type of output coupler is required in conventional architectures to reduce the spread of frequency in the cavity so that the lower power elements can be doubled by a long and very sensitive (but efficient) periodically poled doubling crystal 120. The long length of the doubler 120 in the (>4 mm) requires the use of the VBG 130 to be used to tighten the spread of IR frequencies in the cavity and lock them to the best frequency for the periodically poled doubler 120. Both the long periodically poled doubler 120 and the VBG output coupler 130 have very tight tolerances for wavelength, temperature and alignment, and therefore detrimentally affect the cost and reliability of the whole laser. The VBG 130 reflected the IR light of a limited frequency so that it can pass back through the doubler 120 and which then converts some more of the IR light to the doubled frequency, which is then reflected by the dichroic mirror 160 and then reflected toward the focusing lens 140 by mirror 170. Focusing lens 140 and mirror 170 are not considered inside the cavity. The focusing lens 140 focuses the first and second paths into the multimode fiber 150, which can then pass from the device 100 for use to illuminate an image. The focusing lens 140 and fiber 150 are not necessary, however, as free space beam output can also be desired.

Looking specifically at the light on the first path which is being doubled, the frequency doubler 120 may be a periodically poled lithium niobate crystal (PPLN) as mentioned above, wherein PPLN may be employed rather than a bulk doubling crystal because it may be more efficient at doubling the frequency of the light. This may be employed due to the lower intensities of the VCSEL beams. However, long lengths of PPLN may have a number of significant concerns. First, it may be more expensive than a bulk doubling crystal. Second, in order for PPLN to work well it has very tight tolerances on alignment, wavelength of IR light, and temperature. Thus, the PPLN has to be actively temperature controlled to approximately 0.1 degree Celsius or so, depending on the length of the crystal. Such a tight temperature control system is expensive and is challenging from a reliability point of view.

The wavelength spread that the PPLN can double effectively is also very challenging. Depending on length of the PPLN this can be as little as 0.1nm, typically. This tight tolerance typically requires the use of a wavelength control device, such as a VBG in the cavity as described in the conventional architecture of FIG. 1, so that all the elements of the array can be effectively doubled. Typically, the appropriate narrow bandwidth may indicate that a simple etalon may not be used to narrow the bandwidth. Consequently, a difficult to fabricate volume Bragg grating is typically employed as the output coupler 130. In volume manufacturing, this volume grating can be the most expensive element in the optical system. Both the PPLN and the VBG have tight angular tolerances as well, making volume manufacturing of the overall structure and operation over temperature changes difficult to achieve. As such, low power devices of a few watts have been made using this approach, but manufacturing such devices for high power applications is far more problematic.

Princeton Optronics of Mercerville, N.J., has been able to manufacture VCSELs with unique properties. The individual VCSEL elements can exhibit high power, for example, greater than approximately 150 mW; are very reliable, for example, greater than 100,000 hours; and have good optical quality, which may include microlenses fabricated on the VCSEL elements for improving energy capture. The VCSELs and corresponding properties are generally discussed in U.S. Pat. No. 6,888,871, “VCSEL and VCSEL Array Having Integrated Microlenses For Use In A Semiconductor Laser Pumped Solid State System” and “High Power VCSEL Mature Into Production”, Laser Focus World, April 2011, pp. 61-65, both of which are herein incorporated by reference in their entirety for all purposes.

Using high power IR VCSEL element(s), a bulk crystal doubling material or short periodically poled crystal or other doubling materials can be used to double the IR light and generate “visible” light, such as red, green, blue, or UV light, in an external cavity in either continuous wave or pulsed mode. By using a bulk crystal (such as KTP) all the elements of a large (possibly square) two-dimensional VCSEL array can be frequency doubled simultaneously in the same large doubling crystal, which results in a very high second harmonic power. Since PPLN is typically manufactured in 500 um thick wafers due to the restrictions of the poling process, this limits the dimensions of the conventional VCSEL array that can be doubled with a single PPLN crystal, resulting in lower total second harmonic power. With the disclosed principles, the reflectivity of the output distributed Bragg reflector of these VCSELs can be designed to increase the power in an external cavity, rather than the power in the VCSEL laser. By enabling the use of a short length or bulk doubling material and directly doubling the frequency of the light output from VCSEL, a device constructed in accordance with the disclosed principles can be inexpensive, simpler, high efficiency, better reliability, and have vastly improved manufacturing and alignment tolerances. There are a number of cavity architectures that can be used to double the IR light from such high power VCSEL(s). The VCSEL(s) can be single elements, or arrays with high intensity elements. The arrays may be designed for high power per element and may be designed and fabricated to increase power in the external cavity, which is defined by the disclosed principles as being between the VCSEL element(s) and a frequency-dependent highly reflective/anti-reflective (HR/AR) or highly reflective/highly reflective (HR/HR) (depending on the application, as described in further detail below) structure immediately following the bulk doubling material. The arrays can be fabricated and appropriately cooled so that the spread in wavelength is within the acceptable use of the doubling material.

FIG. 2 is a schematic diagram illustrating one embodiment of architecture for a VCSEL array system 200 in accordance with the disclosed principles. FIG. 2 illustrates one example of an architecture that uses a 2D VCSEL array 210 of high power elements to generate visible light. Additionally, FIG. 2 illustrates intra-cavity 220 frequency doubling of multiple, high power, IR beams from a VCSEL array 210 using bulk doubling material 230 positioned in the cavity 220. The doubled light from the cavity 220 can be used directly, or as shown in FIG. 2, it can be coupled into a multimode optical fiber 260 using a focusing lens 240 or a combination of a micro-lens array 250 and a lens 240, or any combination thereof. However, once again the focusing lens 240 and fiber 260 are optional.

The 1D or 2D array of high power VCSEL element(s) 210 generate IR light and can have integrated micro-lenses (not illustrated) fabricated on top to improve the beam intensity in the cavity 220. The doubling material 230 may generate the visible light by a non-linear conversion process such as, but not limited to, frequency doubling or second harmonic generation, and can include type I and/or type II phase matching. Examples of typical bulk doubling crystals for the doubling material 230 may include, but are not limited to, BBO (barium borate), KDP (potassium dihydrogen phosphate), KTP (potassium titanyl phosphate—as illustrated), lithium niobate, LBO (lithium triborate), KnbO3 (potassium niobate), and so forth. Additionally, other types of doubling materials 230 besides crystals exist and can be used including, but not limited to, non-linear polymers, organic materials, and so forth.

An IR mirror 270 may be included on the other side of the doubling material 230. This IR mirror 270 may have a high reflective (HR) coating to the IR wavelengths and/or an anti-reflective (AR) coating for the visible wavelengths. With these coatings, non-doubled light (e.g., 1064nm) will be reflected back from the IR mirror 270 into the doubling material 230 and to the VCSEL array 210, while frequency doubled light (e.g., 532nm) passes through the IR mirror 270 to be output from the device 200. In this embodiment, the IR mirror 270 forms one end of the cavity as the reflected light can also be doubled and reflected out of the cavity.

The VCSEL array system 200 may employ 1064 nm and 532 nm as examples of IR and visible wavelengths, respectively, but many other wavelengths can be generated. These lasers may be directly doubled, thus a wide range of IR wavelengths can be used to generate visible light from the red to the UV wavelength, or in the approximate range of 700 nm to 350nm. In the embodiment shown in FIG. 2, the doubling is considered intra-cavity since the doubler 230 is positioned inside of the cavity 220 formed by the VCSEL array 210 and the IR mirror 270, in accordance with the disclosed principles. If the VCSEL elements on the array 210 are pulsed, external doubling can be done without the IR mirror 270 due to increase in intensity of the pulses. More specifically, in external doubling, VCSEL array 210 is self-lasing and an external output coupler (e.g., mirror 270) is not present to form the cavity 220. (Alternatively, it may simply be said that the cavity 220 is formed between the VCSEL array 210 and the output or far side of the doubling material 230). Instead, the output from the VCSEL array 210 is directly coupled to the doubling material 230. Because the IR beam is not inside a resonant cavity 220 per se, the intensity is lower, thus reducing the doubling which is power-dependent. Accordingly, since the output from a pulsed VCSEL array is much higher than continuous mode, the frequency doubling becomes more practical and efficient.

In other embodiments, instead of an IR mirror 270 with a HR coating for IR light and an AR coating for visible light, these coatings (280) can be fabricated directly onto the surface of the doubling material 230. The coating 280 may be fabricated on the side away from the VCSEL array 210. This may eliminate one element (e.g., the IR mirror 270) and may increase the likelihood of alignment with the doubling material 230. In addition to the AR and HR coatings, a protective coating (not illustrated) such as SiO2 may be located on the outside and/or inside of these HR and AR coatings 280. The protective coatings and/or layers can be applied to either the separate mirror element IR mirror 270, or in the case of the coatings 280 being incorporated, into the doubling material 230.

The doubling material 230 may also have AR coatings on both sides, or may be Brewster cut (in which the cut surface has an angle which may be at or near the Brewster angle) to substantially minimize reflections. A Brewster cut doubler may also improve the polarization purity of the intra-cavity power and thereby improve doubling efficiency.

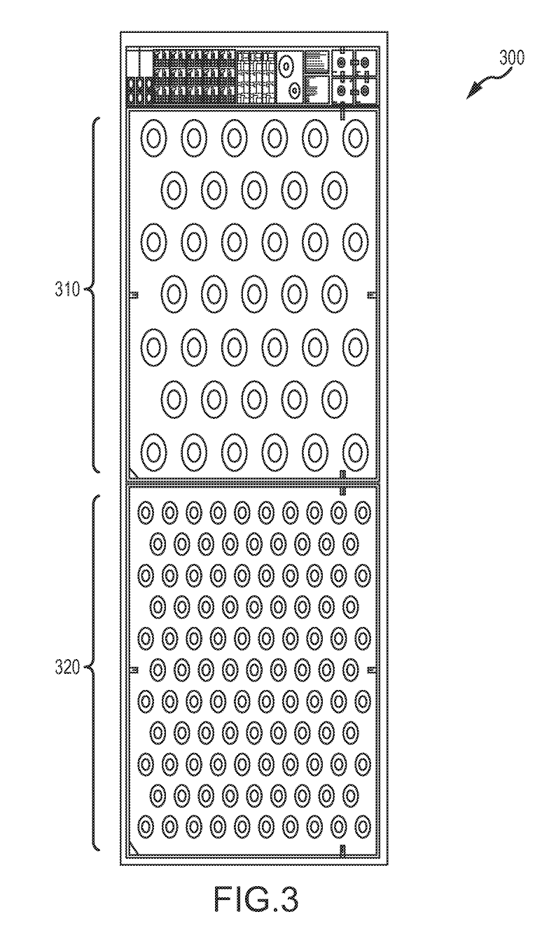

FIG. 3 is a schematic diagram illustrating one embodiment 300 of various VCSEL array layouts in accordance with the disclosed principles. The top VCSEL array layout 310 of FIG. 3 illustrates a pattern of approximately 39,300 micron aperture VCSEL elements. The bottom VCSEL array layout 320 of FIG. 3 illustrates an array of approximately 105,200 micron aperture VCSEL arrays. The VCSEL elements can be different sizes with the goal of making the aperture larger to increase the power/intensity, but keeping the aperture small enough that the optical quality may be appropriate for effective doubling. Typical ranges of VCSEL size may be in the approximate range between 10 microns and 1 mm. The arrangement can be as shown or in various patterns such as, but not limited to, vertical or horizontal rows. The spacing may be determined by the need to cool the array. Designing the array to increase the polarization of the light may also be desirable.

Other concerns of a VCSEL array for this type of application may include wavelength diversity and power in the external cavity. The output DBR may be designed to increase the power in the external cavity rather than in the VCSEL laser. A lower reflectivity than what may be typically employed in a standalone VCSEL may result. In one example, to more efficiently double the IR light, it may be phase matched in the doubling crystal. The design, packaging, soldering, processing, and selecting of the VCSEL array may be designed to improve the wavelength and power uniformity across the array. For example, minimizing the heat differential across the array may improve the wavelength and power uniformity across the array. Minimizing the array area and choosing from the middle of the wafer can improve the uniformity. If sufficiently narrow spectrum in wavelength is difficult to achieve, for example, less than 3 nm, then an etalon can be used make the spectrum narrower. An etalon narrows the frequency but not as much when compared to a VBG. Additionally, etalons are much cheaper and have much larger tolerances on temperature and wavelength. The etalon may also be AR coated or coated to reflect the visible light, or angled near Brewster's angle to improve polarization. For display applications, wider spectrums may be desirable for mitigating speckle. If a wider spectrum than what a single device such as a visible laser can efficiently generate, then two or more devices can be used together that have VCSEL arrays that may be designed to operate at slightly different wavelengths.

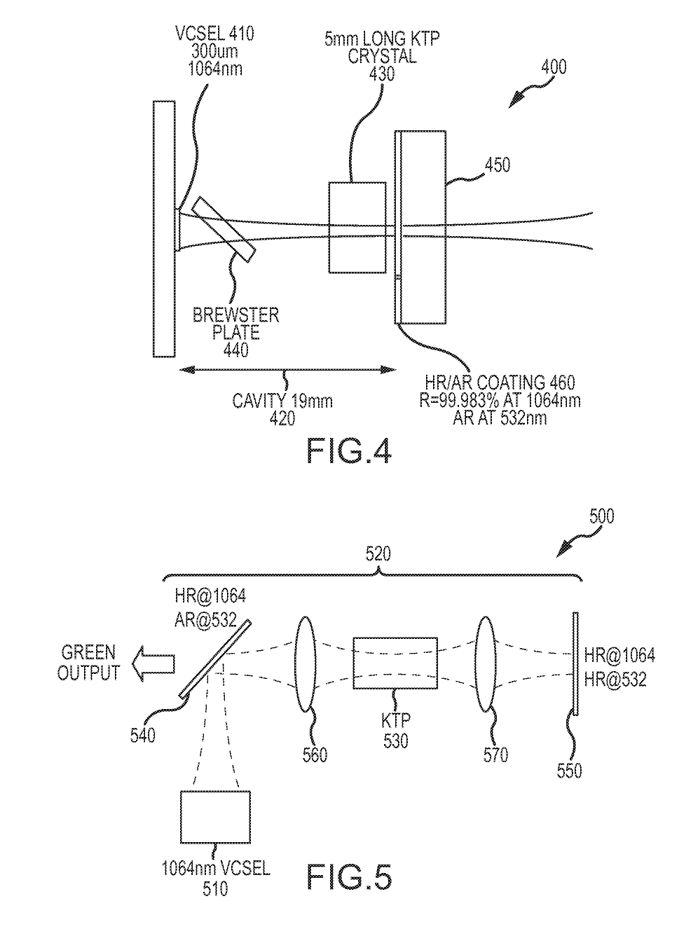

FIG. 4 is a schematic diagram illustrating one embodiment 400 of the doubling of a single VCSEL 410 in accordance with the disclosed principles. The architecture illustrated in FIG. 4 may be used for doubling an array of VCSEL elements as well. Moreover, the VCSEL device 410 may generate light in the 600 nm-1300 nm wavelength range. A Brewster's plate 440 is employed in this exemplary architecture to improve the polarization purity of the IR light generated by the VCSEL element 410. The Brewster's plate 440 may be coated on both sides to substantially minimize IR power loss in the cavity 420 and provide a means of coupling out the doubled light. The Brewster's plate may include a cut surface with an angle approximately at or near Brewster's angle. The light leaves the VCSEL element or array 410 where the polarization may be cleaned up by the Brewster's plate 440, and then the light may enter a doubling material 430, which in the illustrated embodiment of FIG. 4 is shown as KTP crystal.

The length of the doubling material 430 may be a tradeoff in that the longer the material, the better the doubling efficiency, but the tighter the tolerances on angle, temperature and wavelength. Typical lengths for the bulk doubler 430 may be in the approximate range of 1 mm and 30 mm, and in the illustrated embodiment is an exemplary 5 mm long when an exemplary cavity is approximately 19 mm. The output coupler 450 may again be a highly reflective window by being HR and AR coated 460 for the non-doubled and doubled wavelengths, respectively. Again, these coatings 460 can be incorporated onto at least the doubling material's 430 outside surface, away from the VCSEL 410, to eliminate the output coupler 450 in an alternative embodiment.

FIG. 5 is a schematic diagram illustrating one embodiment 500 of architecture for a VCSEL-based system constructed in accordance with the disclosed principles, and in which power may be extracted from the cavity in both directions. Further, FIG. 5 illustrates another architecture in which power may be extracted from the cavity 520 in both directions, which may result in a near doubling of the visible light out, or approximately 80% increase.

The IR VCSEL array 510 may be reflected approximately 45 degrees by a HR mirror 540 in the IR wavelength or folding output coupler or coated etalon. The beam waist may be relayed into the doubling material 530 by a lens 560. After the doubling material 530, another lens 570 may quasi re-collimate the light and substantially both IR and visible light may be reflected by a mirror 550. The light then may return and pass through the doubling material 530 again, which may generate more visible light that may exit the cavity 520 by the mirror 550, which may be HR in the IR wavelength and AR coated for the doubled (visible) wavelength, as illustrated.

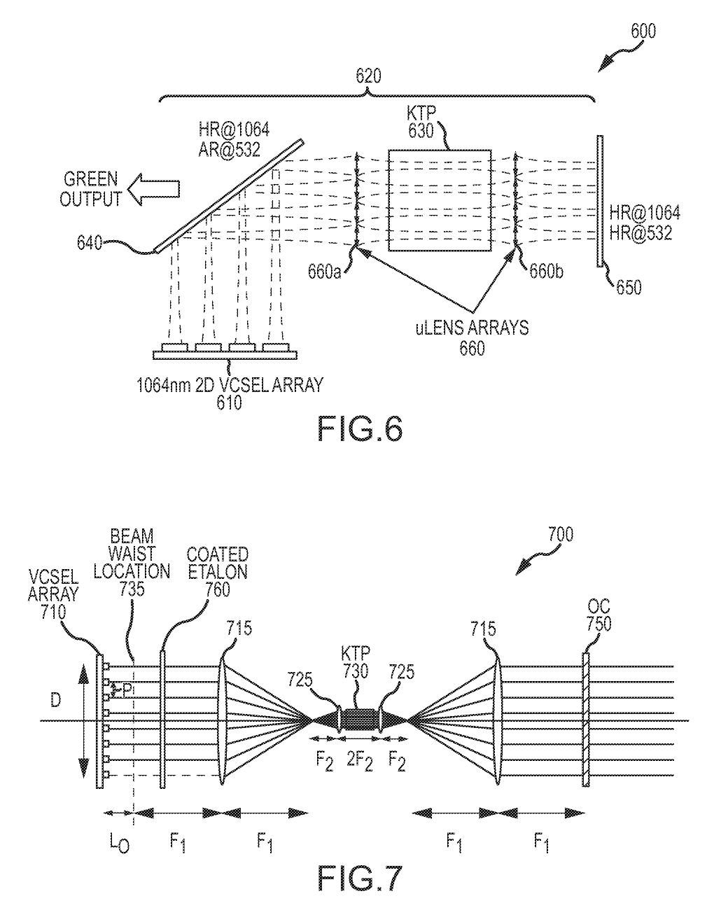

FIG. 6 is a schematic diagram illustrating another embodiment 600 of architecture for a VCSEL-based system constructed in accordance with the disclosed principles, and which may include at least one micro-lens array in the cavity. Specifically, FIG. 6 illustrates a similar architecture to FIG. 5, and thus may include a VCSEL element or array 610, and a HR/AR output coupler 640 and doubling material 630, both in the cavity 620. However, in the embodiment illustrated in FIG. 6, micro-lens arrays 660a, 660b (collectively 660) may be employed instead of converging lenses, as was illustrated in FIG. 5. Roughly, each IR beam may pass through a pre-selected converging micro-lens 660a, and then pass through the doubling material 630 and another micro-lens array 660b, and then may be substantially reflected back by a HR mirror 650 for both IR and doubled wavelengths. The use of intra-cavity lenses (e.g., as shown in FIGS. 5 and 6) to optimize the beam diameter and divergence in the non-linear crystal may further optimize the second harmonic generation conversion efficiency of an architecture constructed according to the disclosed principles. The light may again be extracted by the folding output coupler 640 that may be again HR for IR wavelengths and AR coated for the doubled wavelengths, as discussed above.

Additionally, with respect to FIGS. 5 and 6, the HR mirror (550, 650) may be placed on the outside surface of the doubling material (530, 630). More specifically, the focal plane of the lenses (560, 660), which may be either macro or micro-lens arrays, can be located near or at the outside surface of the doubling material (530, 630), and a mirror at this surface may substantially reflect the visible and IR light back through the doubling material (530, 630), the lens (560, 660a), and output coupler (540, 640). This may fold the cavity (520, 620) without the use of additional elements.

FIG. 7 is a schematic diagram illustrating one embodiment 700 employing a 4F system intra-cavity in a VCSEL-based system. FIG. 7 illustrates the use of a 4F (2F₁, 2F₂) system including a VCSEL array 710, and in which two lenses (715, 725) with their image and object planes separated by approximately 4 focal lengths to image the beam waist (location denoted as 735) into a doubling material (e.g., KTP) 730. Another 4F system and output coupler 750, HR for IR wavelengths and AR for visible wavelengths, may be used to substantially collimate the beam and generate the retro reflection. An optional etalon 760 may decrease the wavelength range of the VCSEL array 710 to improve doubling efficiency. In the illustrated embodiment, L_{O} is the distance from the VCSEL element to the focus of the output beam. L_{O} can be positive or negative, as in the case of a diverging beam with a virtual focus.

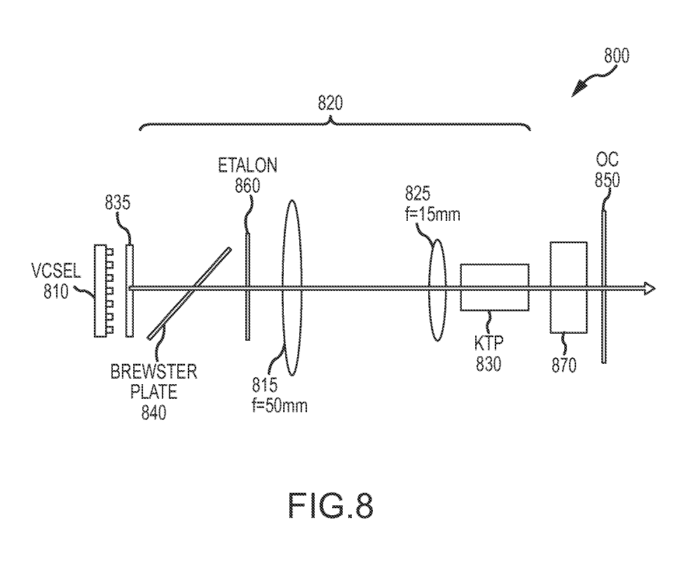

FIG. 8 is a schematic diagram 800 illustrating one embodiment of a VCSEL-based system having a 4F system like the embodiment illustrated in FIG. 7, and employing an output coupler to fold the 4F system. As illustrated in the system of FIG. 8, the first 4F system may image the beam waist (location denoted by 835) to the other side of the doubling material 830, and an output coupler 850, or equivalent coating on the doubling material 830 as discussed above, may be placed at that location. The cavity 820 can also be folded with an output coupler 840, such as the illustrated Brewster's plate 840, between the first lens 815 and the VCSEL array 810, as illustrated in FIGS. 5 and 6. The current output coupler 850 may be replaced with a HR mirror for both IR and visible wavelengths, as disclosed in embodiments discussed above, and the visible light extracted with the folded output coupler 840, which may result in more visible power being extracted due to the IR beams passing though the doubler 830 twice before being extracted from the cavity 820.

For pulsed operation, a saturable absorber, an acoustic optical modulator, electro-optic modulator, and so forth can be placed in the cavity 820 to cause pulsing or to sync pulsing to another element in the system. In a system in which any of these elements may be employed, the elements may be included in a quasi-collimated space in the cavity 820. A possible location for a pulse inducing element may be illustrated as component 870 to the right of the KTP doubling material 830 in FIG. 8. Alternatively, the VCSEL array 810 can be pulsed to operate the laser in pulsed mode.

Combinations of the various architectures and cavity elements disclosed and described herein may also be used, as will be understood by one skilled in the art.

It should be noted that embodiments of the present disclosure may be used in a variety of optical systems and projection systems. Exemplary embodiments may include or work with a variety of projectors, projection systems, optical components, computer systems, processors, self-contained projector systems, visual and/or audiovisual systems, and electrical and/or optical devices. Aspects of the present disclosure may be used with practically any apparatus related to optical and electrical devices, optical systems, display systems, presentation systems or any apparatus that may contain any type of optical system. Accordingly, embodiments of the present disclosure may be employed in optical systems, devices used in visual and/or optical presentations, visual peripherals and so on and in a number of computing environments including the Internet, intranets, local area networks, wide area networks and so on.

Before proceeding to the disclosed embodiments in detail, it should be understood that the illustrated embodiments discussed herein are not limited in application or creation to the details of the particular arrangements shown, because the embodiments are capable of other arrangements. Moreover, aspects of the embodiments may be set forth in different combinations and arrangements to define embodiments unique in their own right. Also, the terminology used herein is for the purpose of description and not of limitation.

As may be used herein, the terms “substantially” and “approximately” provide an industry-accepted tolerance for its corresponding term and/or relativity between items. Such an industry-accepted tolerance ranges from less than one percent to ten percent and corresponds to, but is not limited to, component values, angles, et cetera. Such relativity between items ranges between less than one percent to ten percent.

While various embodiments in accordance with the principles disclosed herein have been described above, it should be understood that they have been presented by way of example only, and not limitation. Thus, the breadth and scope of this disclosure should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” the claims should not be limited by the language chosen under this heading to describe the so-called field. Further, a description of a technology in the “Background” is not to be construed as an admission that certain technology is prior art to any embodiment(s) in this disclosure. Neither is the “Summary” to be considered as a characterization of the embodiment(s) set forth in issued claims. Furthermore, any reference in this disclosure to “invention” in the singular should not be used to argue that there is only a single point of novelty in this disclosure. Multiple embodiments may be set forth according to the limitations of the multiple claims issuing from this disclosure, and such claims accordingly define the embodiment(s), and their equivalents, that are protected thereby. In all instances, the scope of such claims shall be considered on their own merits in light of this disclosure, but should not be constrained by the headings set forth herein.

What is claimed is:

1. An architecture for a vertical cavity surface emitting laser system, the architecture comprising:
at least one vertical cavity surface emitting laser (VCSEL) element;
a doubling material located in a cavity adjacent to the VCSEL element and configured to receive light emitted from the VCSEL element, and to substantially double the frequency of the received light; and
an output coupler configured to output the doubled light from the cavity.

2. The architecture of claim 1, wherein the light emitted from the VCSEL element comprises infrared light, and the doubled light comprises visible light selected from the group consisting of red, green, blue, or ultraviolet light.

3. The architecture of claim 2, wherein the at least one VCSEL element comprises a two dimensional array of VCSEL elements.

4. The architecture of claim 1, further comprising a mirror at an end of the cavity opposite to the at least one VCSEL element, the mirror being highly reflective of non-visible light in the infrared spectrum, and anti-reflective for light in the visible spectrum.

5. The architecture of claim 1, further comprising a coating on an end of the doubling material opposite to the at least one VCSEL element, the coating being highly reflective of non-visible light in the infrared spectrum, and anti-reflective for light in the visible spectrum.

6. The architecture of claim 1, further comprising a cut surface with an angle approximately near the Brewster angle located between the at least one VCSEL element and the doubling material, and configured to improve the polarization purity of the light generated by the at least one VCSEL element.

7. The architecture of claim 6, wherein the cut surface with an angle approximately near the Brewster angle comprises a Brewster's plate located between the at least one VCSEL element and the doubling material, wherein the Brewster's plate comprises a coating being highly reflective of non-visible light in the infrared spectrum, and anti-reflective for light in the visible spectrum.

8. The architecture of claim 6, wherein the cut surface with an angle approximately near the Brewster angle is provided on the doubling material.

9. The architecture of claim 1, wherein the output coupler comprises an angled mirror at an end of the cavity adjacent to the at least one VCSEL element, the angled mirror being highly reflective of non-visible light in the infrared spectrum and anti-reflective for light in the visible spectrum, and wherein non-visible light emitted from the at least one VCSEL element is reflected by the angled mirror into the doubling material and visible light exiting the doubling material passes through the mirror out of the cavity.

10. The architecture of claim 9, further comprising a second mirror at an end of the cavity opposite to the output coupler and the at least one VCSEL element, the second mirror being highly reflective of both non-visible and visible light such that said light received from the doubling material is reflected back into the doubling material and towards the output coupler.

11. The architecture of claim 10, further comprising converging lens located on opposing ends of the doubling material between the output coupler and the second mirror.

12. The architecture of claim 10, further comprising micro-lens arrays located on opposing ends of the doubling material between the output coupler and the second mirror.

13. The architecture of claim 1, wherein the at least one VCSEL element is operable in either one of a continuous wave or pulsed mode.

14. The architecture of claim 1, wherein the doubling material doubles the frequency of the light by a non-linear conversion process such as frequency doubling or second harmonic generation.

15. The architecture of claim 1, wherein the doubled light is coupled into a multimode optical fiber using a focusing lens, one or more micro-lens arrays, or a combination thereof.

16. The architecture of claim 1, further comprising a 4F lens system within the cavity and proximate the at least one VCSEL element, the 4F system comprising two lenses with the image and object planes separated by 4 focal lengths and configured to image the beam waist of light emitted from the at least one VCSEL element into the doubling material.

17. The architecture of claim 16, further comprising a second 4F system within the cavity and proximate to the output coupler, the second 4F system configured to substantially collimate the doubled light from the doubling material.

18. The architecture of claim 16, further comprising an etalon between the at least one VCSEL element and the 4F system, the etalon configured to decrease the wavelength range of light emitted from the at least one VCSEL element.

19. The architecture of claim 1, wherein the doubling material comprises crystals selected from the group consisting of barium borate, potassium dihydrogen phosphate, potassium titanyl phosphate, lithium niobate, lithium triborate, and potassium niobate.

20. An architecture for a vertical cavity surface emitting laser system, the architecture comprising:
at least one vertical cavity surface emitting laser (VCSEL) element configured to emit infrared light;
a cavity defined between the at least one VCSEL element and a mirror being highly reflective of infrared light; and
a doubling material located in the cavity and configured to receive infrared light emitted from the VCSEL element, and to substantially double the frequency of the received infrared light to output visible light.

21. The architecture of claim 20, further comprising an output coupler configured to receive the visible light from the cavity for use in display illumination.

22. The architecture of claim 21, wherein the mirror is highly reflective of non-visible light in the infrared spectrum, and anti-reflective for light in the visible spectrum, and wherein the output coupler is located adjacent to the mirror outside the cavity.

23. The architecture of claim 21, wherein the output coupler comprises an angled second mirror at an end of the cavity adjacent to the at least one VCSEL element, wherein the angled second mirror is highly reflective of non-visible light in the infrared spectrum and anti-reflective for light in the visible spectrum, and wherein non-visible light emitted from the at least one VCSEL element is reflected by the angled mirror into the doubling material and visible light exiting the doubling material passes through the angled mirror out of the cavity.

24. The architecture of claim 23, wherein the first mirror is highly reflective of both non-visible and visible light such that light received from the doubling material is reflected back into the doubling material and towards the angled second mirror.

25. The architecture of claim 24, further comprising converging lens located on opposing ends of the doubling material between the first mirror and the angled second mirror.

26. The architecture of claim 24, further comprising micro-lens arrays located on opposing ends of the doubling material between the first mirror and the angled second mirror.

27. The architecture of claim 20, further comprising a cut surface with an angle approximately near the Brewster angle located between the at least one VCSEL element and the doubling material, and configured to improve the polarization purity of the light generated by the at least one VCSEL element.

28. The architecture of claim 27, wherein the cut surface with an angle approximately near the Brewster angle comprises a Brewster's plate located between the at least one VCSEL element and the doubling material, wherein the Brewster's plate comprises a coating being highly reflective of non-visible light in the infrared spectrum, and anti-reflective for light in the visible spectrum.

29. The architecture of claim 27, wherein the cut surface with an angle approximately near the Brewster angle is provided on the doubling material.

30. The architecture of claim 20, wherein the VCSEL element is operable in either one of a continuous wave or pulsed mode.

31. The architecture of claim 20, wherein the doubling material doubles the frequency of the light by a non-linear conversion process such as frequency doubling or second harmonic generation.

32. The architecture of claim 20, wherein the doubled light is coupled into a multimode optical fiber using a focusing lens, one or more micro-lens arrays, or a combination thereof.

33. The architecture of claim 20, wherein the doubling material comprises crystals selected from the group consisting of barium borate, potassium dihydrogen phosphate, potassium titanyl phosphate, lithium niobate, lithium triborate, and potassium niobate.

34. The architecture of claim 20, wherein the at least one VCSEL element comprises a two dimensional array of VCSEL elements.

35. An architecture for a vertical cavity surface emitting laser system, the architecture comprising:
at least one vertical cavity surface emitting laser (VCSEL) element configured to emit infrared light;
a doubling material located in a cavity adjacent to the VCSEL element and configured to receive infrared light emitted from the at least one VCSEL element, and to substantially double the frequency of the received infrared light to output visible light;
a coating on an end of the doubling material opposite to the at least one VCSEL element, the coating being highly reflective of infrared light; and
an output coupler configured to receive the doubled light from the doubling material.

36. The architecture of claim 35, wherein the output coupler defines an end of the cavity opposite the at least one VCSEL element, and wherein the coating is highly reflective of infrared light and anti-reflective of visible light.

37. The architecture of claim 35, further comprising a cut surface with an angle approximately near the Brewster angle located between the at least one VCSEL element and the doubling material, and configured to improve the polarization purity of the light generated by the at least one VCSEL element.

38. The architecture of claim 37, wherein the cut surface with an angle approximately near the Brewster angle comprises a Brewster's plate located between the at least one VCSEL element and the doubling material, wherein the Brewster's plate comprises a coating being highly reflective of non-visible light in the infrared spectrum, and anti-reflective for light in the visible spectrum.

39. The architecture of claim 37, wherein the cut surface with an angle approximately near the Brewster angle is provided on the doubling material.

40. The architecture of claim 35, wherein the coating is highly reflective of both infrared and visible light, and wherein the output coupler comprises an angled mirror at an end of the cavity adjacent to the at least one VCSEL element, the angled mirror being highly reflective of non-visible light in the infrared spectrum and anti-reflective for light in the visible spectrum, and wherein non-visible light emitted from the at least one VCSEL element is reflected by the angled mirror into the doubling material and visible light exiting the doubling material passes through the mirror out of the cavity.

41. The architecture of claim 35, wherein the at least one VCSEL element is operable in either one of a continuous wave or pulsed mode.

42. The architecture of claim 35, wherein the doubling material doubles the frequency of the light by a non-linear conversion process such as frequency doubling or second harmonic generation.

43. The architecture of claim 35, wherein the doubling material comprises crystals selected from the group consisting of barium borate, potassium dihydrogen phosphate, potassium titanyl phosphate, lithium niobate, lithium triborate, and potassium niobate.

44. The architecture of claim 35, wherein the at least one VCSEL element comprises a two dimensional array of VCSEL elements.
